(19) United States
(12) Patent Application Publication
(10) Pub. No.: US 2010/0276730 A1
(43) Pub. Date: Nov. 4, 2010

(54) SEMICONDUCTOR DEVICE

(75) Inventor: Doyeol AHN, Seoul (KR)

Correspondence Address: Workman Nydegger;1000 Eagle Gate Tower, 60 East South Temple, Salt Lake City, UT, 84111, US

(73) Assignee: University of Seoul Industry Cooperation Foundation, Seoul (KR)

(21) Appl. No.: 12/431,921

(22) Filed: Apr. 29, 2009

(51) Int. Cl. H01L 29/165

(52) U.S. Cl. 257/183; 257/103; 257/E29.085

(57) ABSTRACT

Semiconductor devices having at least one barrier layer are disclosed. In some embodiments, a semiconductor device includes an active layer and one or more barrier layers disposed on either one side or both sides of the active layer. The active layer may be composed of a first compound semiconductor material, and the one or more barrier layers may be composed of a second compound semiconductor material. In some embodiments, the composition of the one or more barrier layers may be adjusted to increase an optical dipole matrix element.

### BACKGROUND

Group III-V compound and Group III-VI compound semiconductors have particularly wide band gaps and are capable of emitting green or blue light. Recently, semiconductor devices, such as photo-electric conversion devices using III-V or II-VI group compound semiconductor crystals as base materials have been developed to improve efficiency and life time of the semiconductor devices.

However, one drawback to Group III-V compound and Group II-VI compound semiconductors are their poor optical gain characteristics.

### SUMMARY

In one embodiment, a semiconductor device includes an active layer and one or more barrier layers disposed on either one side or both sides of the active layer. The active layer may be composed of a first compound semiconductor material, and the one or more barrier layers may be composed of a second compound semiconductor material. In some embodiments, the composition of the one or more barrier layers may be adjusted to increase an optical dipole matrix element.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIGS. 1(a) and 1(b) are schematic diagrams of an illustrative embodiment of a semiconductor device.

FIGS. 2(a) and 2(b) are schematic diagrams showing band gaps of the semiconductor device of FIG. 1.

FIG. 3 is a schematic diagram of an illustrative embodiment of a III-V group compound semiconductor device.

FIG. 4 is a graph showing an internal polarization field as a function of In composition of the AlGaInN barrier layer shown in FIG. 3.

FIG. 5 is a graph showing the relationship between In composition of the InGaN active layer and In composition of the AlGaInN barrier layer shown in FIG. 3.

FIG. 6 is a graph showing normalized optical matrix elements as a function of in-plane vectors for different compositions of the barrier layer shown in FIG. 3.

FIG. 7 is a graph showing an optical gain as a function of wavelength for the InGaN/AlGaInN semiconductor device shown in FIG. 3 and an InGaN/GaN semiconductor device.

FIG. 8 is a schematic diagram of an illustrative embodiment of a II-VI group compound semiconductor device.

FIG. 9 is a graph showing an internal polarization field as a function of Mg composition of the MgZnO barrier layer shown in FIG. 8.

FIG. 10 shows graphs illustrating (a) the relationship between Mg composition of the MgZnO barrier layer and Cd composition of the CdZnO active layer shown in FIG. 8, and (b) a wavelength of the semiconductor device shown in FIG. 8 as a function of Cd composition of the CdZnO active layer.

FIG. 11 shows graphs illustrating (a) an optical gain as a function of wavelength for different mole fractions of Cd compositions of the CdZnO active layer shown in FIG. 8, and (b) an optical gain as a function of different mole fractions of Cd compositions of the CdZnO active layer shown in FIG. 8.

FIGS. 12(a)-12(e) are schematic diagrams illustrating an illustrative embodiment of a method for fabricating a semiconductor device.

### DETAILED DESCRIPTION

In one embodiment, a semiconductor device includes an active layer composed of a first compound semiconductor, and one or more barrier layers disposed on either one side or both sides of the active layer and composed of a second compound semiconductor material. The composition of the barrier layer can be adjusted to increase an optical dipole matrix element of the active layer.

The optical dipole matrix element can be increased by making the sum of an internal polarization field of the active layer and an internal polarization field of the one or more barrier layers zero. The composition of the active layer can be controlled in accordance with the composition of the one or more barrier layers. A band gap of the first compound semiconductor material is smaller than that of the second compound semiconductor material.

The second compound semiconductor material can include a ternary or a quaternary compound semiconductor material. The first and second compound semiconductor materials can each include a III-V group compound semiconductor material or a II-VI group compound semiconductor material. The first compound semiconductor material can include, for example, GaN, InGaN, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, AlGaInAs, ZnO, ZnS, CdO, CdS, CdZnS, CdZnO, MgZnO, MgZnS, CdMgZnO, or CdMgZnS. The second compound semiconductor material can include, for example, AlGaInN, InGaN, AlGaN, AlGaP, AlGaAs, InGaN, InGaP, InGaAs, InAlN, InAlP, InAlAs, AlGaInP, AlGaInAs, CdZnS, CdZnO, MgZnO, MgZnS, CdMgZnO, or CdMgZnS.

In one embodiment, the first compound semiconductor material can be composed of InₓGa₁₋ₓN (0≦x≦1), and the second compound semiconductor material can be composed of AlGa_{1-y}In_{y}N (0≦y≦1). The variable x can be in the range of about 0 and 0.30 and the variable y can be in the range of about 0.01 and 0.30. The relation between x and y may be linear.

In another embodiment, the first compound semiconductor material can be composed of CdₓZn₁₋ₓO (0≦x≦1), and the second compound semiconductor material can be composed of Mg_{y}Zn_{1-y}O (0≦y≦1). The variable x can be in the range of about 0 and 0.20 and the variable y can be in the range of about 0.01 and 0.80. The relation between x and y may be logarithmic.

The thickness of the active layer may be in the range of about 0.1 nm and 300 nm. The thickness of the one or more barrier layers may each be in the range of about 0.1 nm and 500 nm.

In another embodiment, a method for fabricating a semiconductor device is provided. An active layer composed of a first compound semiconductor material can be formed on a substrate. One or more barrier layers can be formed on either one side or both sides of the active layer. The barrier layer can be composed of a second compound semiconductor material. The composition of the barrier layer can be adjusted to increase an optical dipole matrix element of the active layer. The first compound semiconductor material can include a III-V group compound semiconductor material or a II-VI group compound semiconductor material. The second compound semiconductor material can include a quaternary group compound semiconductor material or a ternary group compound semiconductor material. The active layer or the one or more barrier layers can be formed by, for example, radio-frequency (RF) magnetron sputtering, pulsed laser deposition, metal organic chemical vapor deposition (MOCVD), molecular beam epitaxy or radio-frequency plasma-excited molecular beam epitaxy. The composition of the one or more barrier layers can be adjusted by controlling the amount of precursor gases or by controlling a processing temperature or processing time.

In the following detailed description, reference is made to the accompanying drawings, which form a part hereof In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

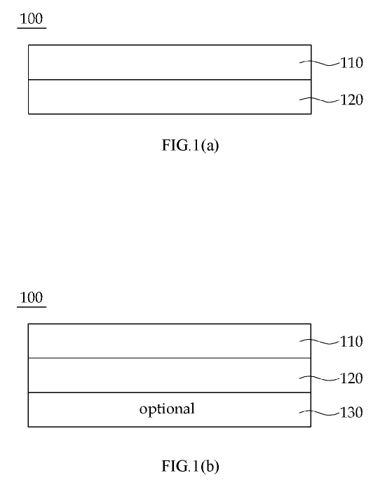

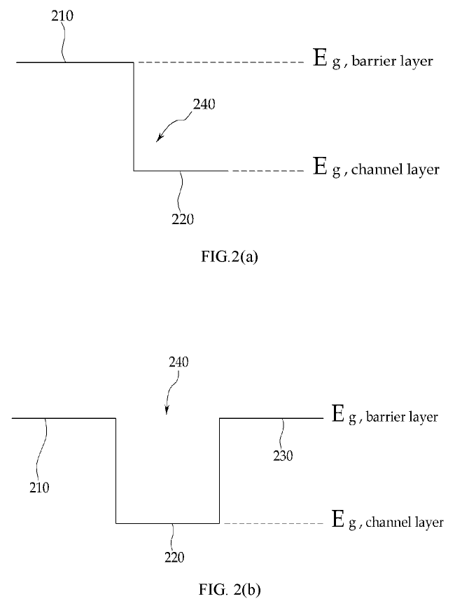

With reference to FIGS. 1 and 2, a semiconductor device in accordance with the present disclosure will now be described. FIGS. 1(a) and 1(b) are schematic diagrams of an illustrative embodiment of a semiconductor device 100. FIGS. 2(a) and 2(b) are schematic diagrams showing band gaps of semiconductor device 100. As depicted in FIG. 1(a), semiconductor device 100 may have a single heterostructure in which a barrier layer 110 is disposed on an active layer 120. Barrier layer 110 has a band gap that is wider than the band gap of active layer 120. Accordingly, as depicted in FIG. 2(a), a band gap (E_{g,active layer}) 220 of active layer 120 is lower than a band gap (E_{g,barrier layer}) 210 of barrier layer 110, so that a quantum well 240 is formed in active layer 120. E_{g,active layer} is the difference between E_{c} and Eᵥ at active layer 120 and E_{g,barrier layer} is the difference between E_{c} and Eᵥ at barrier layer 110. E_{c} refers to an energy level at a conduction band of a semiconductor material, for example, a III-V group or a II-VI group compound semiconductor material. Eᵥ refers to an energy level at a valence band of a semiconductor material, for example, a III-V group or a II-VI group compound semiconductor material. Quantum well 240 is a thin layer which can confine carriers, such as electrons or holes, in a dimension perpendicular to the layer surface. Due to the band gap differences between active layer 120 and barrier layer 110, particles, such as electrons or holes, can be confined in quantum well 240.

As depicted in FIG. 1(b), semiconductor device 100 may optionally have a double heterostructure in which active layer 120 can be sandwiched between two barrier layers (e.g., barrier layer 110 and a second barrier layer 130), each having a wider band gap than that of active layer 120. For purpose of illustration, barrier layers 110 and 130 are hereinafter referred as upper and lower barrier layers 110 and 130, respectively. Quantum well 240 is also formed in active layer 120 because of the differences between band gap (E_{g,active layer}) 220 of active layer 120 and band gaps (E_{g,upper barrier layer}) 210 and (E_{g,lower barrier layer}) 230 of upper and lower barrier layers 110 and 130, as shown in FIG. 2(b).

In some embodiments, active layer 120 may be composed of a III-V group compound semiconductor material or a II-VI group compound semiconductor material. III-V group semiconductor materials include, without limitation, GaN, InGaN, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP or AlGaInAs. II-VI group semiconductor materials include, without limitation, ZnO, ZnS, CdO, CdS, CdZnO, CdZnS, MgZnO, MgZnS, CdMgZnO, or CdMgZnS. Active layer 120 can have a thickness of about 0.1 nm to 300 nm, or about 1 nm to 50 nm.

Upper and lower barrier layers 110 and 130 may be composed of a III-V group compound semiconductor material or a II-VI group compound semiconductor material. In some embodiments, upper and lower barrier layers 110 and 130 may also be composed of a ternary compound semiconductor material or a quaternary compound semiconductor material. Examples of ternary or quaternary III-V group compound semiconductor materials include, without limitation, AlGaInN, InGaN, AlGaN, AlGaP, AlGaAs, InGaN, InGaP, InGaAs, InAlN, InAlP, InAlAs, AlGaInP or AlGaInAs. Examples of ternary or quaternary II-VI group compound semiconductor materials include, without limitation, CdZnS, MgZnS, CdZnO, MgZnO, CdMgZnO, or CdMgZnS. Upper and lower barrier layers 110 and 130 may each have a thickness of about 0.1 nm to 500 nm, or about 1 nm to 100 nm.

A quantum efficiency is a quantity defined as the percentage of photons that produces an electron-hole pair, and can be measured by, for example, an optical gain of a semiconductor device. An optical gain g(ω) can be calculated by using a non-Markovian model with many-body effects due to interband transitions. The “many-body effects” refer to a band gap renormalization and an enhancement of optical gain due to attractive electron-hole interaction (Coulomb or excitonic enhancement). Optical gain g(ω) is given by Equation (1) as below. For theory on the optical gain, see Doyeol Ahn, “Theory of Non-Markovian Gain in Strained-Layer Quantum-Well Lasers with Many-Body Effects”, IEEE Journal of Quantum Electronics, Vol. 34, No. 2, pp. 344-352 (1998), and Ahn et al., “Many-Body Optical Gain and Intraband Relaxation Time of Wurtzite InGaN/GaN Quantum-Well Lasers and Comparison with Experiment”, Appl. Phys. Lett. Vol. 87, p. 044103 (2005), which are incorporated by reference herein in their entireties.

$$g ( ω ) = \frac{ωμ c}{{n}_{r} V} {\sum }_{ση lm} {\sum }_{{\vec{k}}_{\vert \vert}} {\vert \hat{ɛ} \cdot {M}_{lm}^{ησ} ( {\vec{k}}_{\vert \vert} ) \vert}^{2} ( {f}_{c} - {f}_{h σ} ) {C}_{lm}^{η σ} ( {\vec{k}}_{\vert \vert} ) \qquad Equation ( 1 )$$

where ω is an angular frequency of photon in active layer 120; μ is a vacuum permeability; nᵣ is a refractive index of active layer 120; c is the speed of light in free space; V is the volume of active layer 120; ƒ_{c} and ƒ_{hσ} are the Fermi functions for conduction band and valence band of H^{σ}, respectively; Mₗₘ^{η σ}(\vec{k}_{∥}) is the dipole matrix element between the conduction band with a spin state η and the valence band of the 3×3 block Hamiltonian H^{σ}; \hat{ε} is the unit vector in the direction of the photon polarization; and Cₗₘ^{ησ}(\vec{k}_{∥}) is a renormalized lineshape function.

As shown in Equation (1) above, optical gain g(ω) increases in accordance with the increase of an optical dipole matrix element Mₗₘ^{η σ}(\vec{k}_{∥}) for example, the increase of an optical dipole matrix element Mₗₘ^{η σ}(\vec{k}_{∥}) in quantum well 240. The optical dipole matrix element Mₗₘ^{η σ}(\vec{k}_{∥}) increases as the electron-hole separation becomes narrower. Further, the electron-hole separation becomes narrower as an internal polarization field decreases. Accordingly, the optical dipole matrix element Mₗₘ^{η σ}(\vec{k}_{∥}) is largely enhanced due to the disappearance of the internal polarization field. For additional detail on the relationship between the optical dipole matrix element and the internal polarization filed, see Ahn et al., “Optical Gain in InGaN/InGaAlN Quantum Well Structures with Zero Internal Field”, Appl. Phys. Lett. Vol. 92, p. 171115 (2008), which is incorporated by reference herein in its entirety.

An internal polarization field in quantum well 240 arises from a spontaneous polarization P_{SP} and a piezoelectric polarization P_{PZ}. Piezoelectric polarization P_{PZ} refers to a polarization that arises from the electric potential generated in response to applied mechanical stress, such as a strain of a layer. Spontaneous polarization P_{SP} refers to a polarization that arises in ferroelectrics without external electric field. Although piezoelectric polarization P_{PZ} can be reduced by reduction of the strain, spontaneous polarization P_{SP} remains in quantum well 240. For additional detail on spontaneous and piezoelectric polarizations and the internal polarization field, see Ahn et al., “Spontaneous and piezoelectric polarization effects in wurtzite ZnO/MgZnO quantum well lasers”, Appl. Phys. Lett. Vol. 87, p. 253509(2005), which is incorporated herein by reference in its entirety.

Thus, the increasing of optical gain g(ω) is achieved by the reduction of a total internal polarization field including the spontaneous and piezoelectric polarizations. The total internal polarization field F_{z}^{w} in quantum well 240 can be determined from the difference between the sum of spontaneous polarization P_{SP} and piezoelectric polarization P_{PZ} in quantum well 240 and the sum of spontaneous polarization P_{SP} and piezoelectric polarization P_{PZ} in upper and lower barrier layers 110 and 130, as represented by Equation (2) below.

F_{Z}^{W}=[(P_{SP}^{b}+P_{PZ}^{b})−(P_{SP}^{w}+P_{PZ}^{w})]/(ε^{w}+ε^{b} L_{w}/L_{b}) Equation (2)

where P is the polarization, the superscript w and b denote quantum well 240 and upper and lower barrier layers 110 and 130 respectively, L is the thickness of a layer, and ε is the static dielectric constant.

In one embodiment, total internal polarization field F_{z}^{w} can have a value of zero by making sum (P_{SP}^{b}+P_{PZ}^{b}) of the spontaneous and piezoelectric polarizations at upper and lower barrier layers 110 and 130 and the sum (P_{SP}^{w}+P_{PZ}^{w}) of the spontaneous and piezoelectric polarizations at quantum well 240 the same. For example, this can be achieved by controlling the mole fractions of the compound in upper and lower barrier layers 110 and 130, with respect to active layer 120.

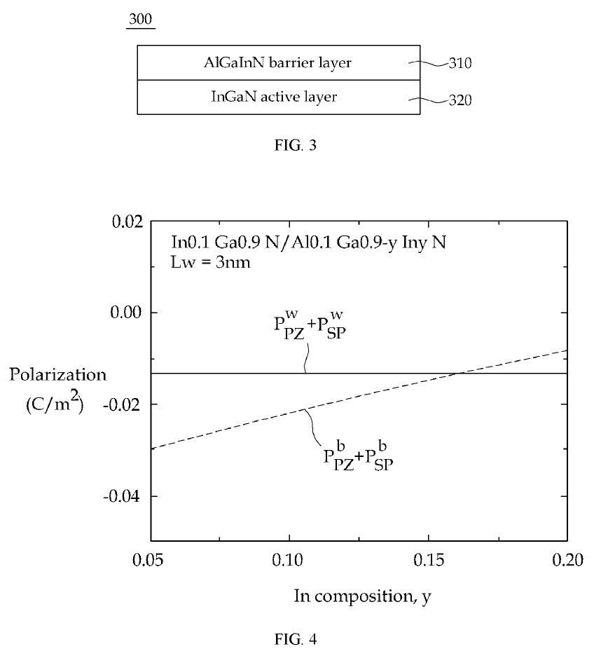

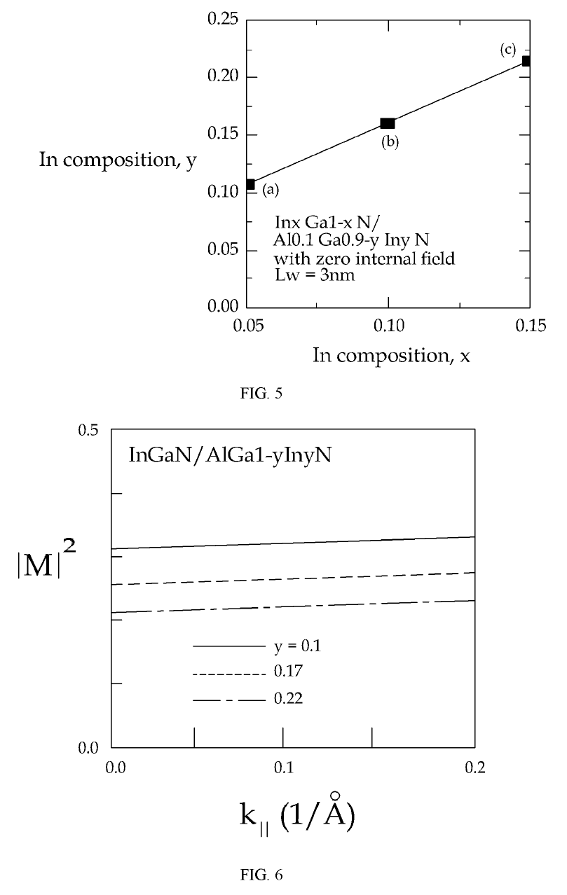

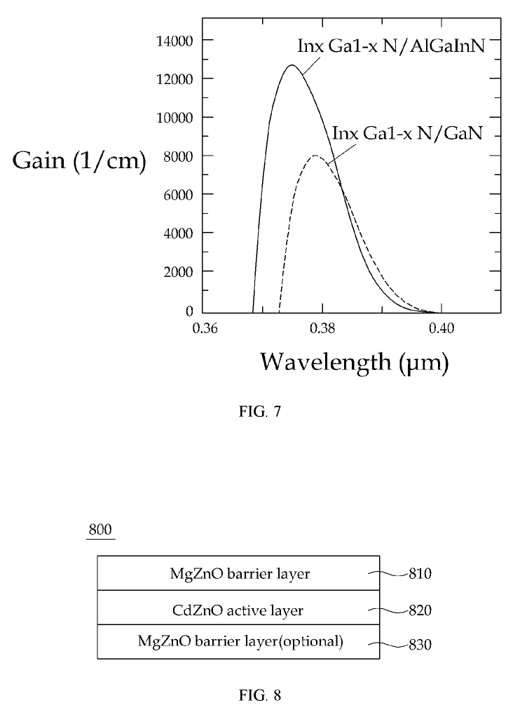

With reference to FIGS. 3-7, a III-V group compound semiconductor device having a minimized internal polarization field will now be described. FIG. 3 is a schematic diagram of an illustrative embodiment of a III-V group compound semiconductor device. FIG. 4 is a graph showing an internal polarization field as a function of In composition of the AlGaInN barrier layer shown in FIG. 3. FIG. 5 is a graph showing the relationship between In composition of the InGaN active layer and In composition of the AlGaInN barrier layer shown in FIG. 3. FIG. 6 is a graph showing normalized optical matrix elements as a function of in-plane vectors for different compositions of the barrier layer shown in FIG. 3. FIG. 7 is a graph showing an optical gain as a function of wavelength for the InGaN/AlGaInN semiconductor device shown in FIG. 3 and an InGaN/GaN semiconductor device.

As depicted in FIG. 3, a III-V group compound semiconductor device 300 includes an InGaN active layer 320 (i.e., an active layer composed of InGaN) and an AlGaInN a barrier layer 310 (i.e., a barrier layer composed of AlGaInN) disposed on InGaN active layer 320. In another embodiment, III-V group compound semiconductor device 300 may optionally have another barrier layer formed under active layer 320. InGaN active layer 320 may have a thickness of several nanometers to several hundreds nanometers (nm). For example, InGaN active layer 320 can have a thickness of about 0.1 nm to 300 nm, or about 1 nm to 50 nm.

AlGaInN barrier layer 310 may have a thickness of several nanometers to several hundreds nanometers (nm). For example, AlGaInN barrier layer 310 may have a thickness of about 0.1 nm to 500 nm, or about 1 nm and to 100 nm. In other embodiments, a III-V group compound semiconductor material having a band gap greater than a band gap of a III-V group compound semiconductor material of the active layer can be selected for the barrier layer.

InGaN active layer 320 has a smaller band gap than the band gap of AlGaInN barrier layer 310, thus forming a quantum well in InGaN active layer 320. For example, the band gap of InGaN active layer 320 is in the range of about 0.7 eV and 3.4 eV, and the band gap of AlGaInN barrier layer 310 is in the range of about 0.7 eV and 6.3 eV. The difference between the band gaps of InGaN active layer 320 and AlGaInN barrier layer 310 can be controlled by adjusting the composition of InGaN active layer 320, the composition of AlGaInN barrier layer 310, or the compositions of both InGaN active layer 320 and AlGaInN barrier layer 310. In some embodiments, aluminum (Al) composition of AlGaInN barrier layer 310 can be controlled so that AlGaInN barrier layer 310 has a larger band gap than that of InGaN active layer 320. For example, the composition of AlGaInN barrier layer 310 can be controlled to achieve a mole fraction of Al composition of the range of about 0.05 to about 0.3, assuming that the total mole value of III group semiconductor materials, that is, Al, In, and Ga is one.

As illustrated with respect to Equation (2) above, the internal polarization field in the quantum well can be reduced by controlling the mole fractions of the compositions of InGaN active layer 320 and AlGaInN barrier layer 310, which will now be described in detail.

The graph shown in FIG. 4 illustrates an internal polarization field (y-axis) depending on the mole fraction of indium (In) composition (x-axis) of barrier layer 310. Here, active layer 320 is composed of In_{0.1}Ga_{0.9}N and has a thickness of 3 nm. Barrier layer 310 is composed of Al_{0.1}Ga_{0.9-y}In_{y}N and has a thickness of about 3 nm to 15 nm. The variable y, which indicates the mole fraction of indium (In) composition of Al_{0.1}Ga_{0.9-y}In_{y}N barrier layer 310, may be controlled such that sum P_{PZ}^{w}+P_{SP}^{w} of the piezoelectric and spontaneous polarizations in active layer 320 and sum P_{PZ}^{b}+P_{SP}^{b} of the piezoelectric and the spontaneous polarizations in barrier layer 310 are substantially the same. The cancellation of the sum of piezoelectric and spontaneous polarizations between the quantum well and the barrier layer makes the total internal polarization field in the active layer zero as defined in Equation (2).

As depicted in FIG. 4, the solid line indicates the sum of the piezoelectric and the spontaneous polarizations (P_{PZ}^{w}+P_{SP}^{w}) in the quantum well, and the dotted or dashed line indicates the sum of the piezoelectric and the spontaneous polarizations (P_{PZ}^{b}+P_{SP}^{b}) in barrier layer 310. An experimental test showed that the solid line meets the dotted line when the indium (In) composition (y) of Al_{0.1}Ga_{0.9-y}In_{y}N barrier layer 310 has a mole fraction of approximately 0.16. Because the sum P_{PZ}^{w}+P_{SP}^{w} of the piezoelectric and the spontaneous polarizations and the sum P_{PZ}^{b}+P_{SP}^{b} of the piezoelectric and the spontaneous polarizations are substantially the same at the point where the solid and dotted lines meet, the total internal polarization field in active layer 320 becomes approximately zero according to Equation (2). Accordingly, when variable y is approximately 0.16, that is, barrier layer 310 has the composition of Al_{0.1}Ga_{0.74}In_{0.16}N, the internal polarization field becomes approximately zero. Through the minimization of the internal polarization field, optical dipole matrix element Mₗₘ^{η σ}(\vec{k}_{∥}) is largely enhanced and optical gain g(ω) of semiconductor device 300 can be maximized in accordance with enhancement of optical dipole matrix element, as illustrated above with respect to Equation (1).

The In composition of active layer 320 and barrier layer 310 can be controlled. The graph shown in FIG. 5 illustrates the relationship between In compositions of InGaN active layer 320 (having a thickness of about 3 nm) and In composition of AlGaInN barrier layer 310 (having a thickness of about 3 nm to 15 nm) when the internal polarization field is zero. In the graph of FIG. 5, x-axis indicates the mole fraction of In composition of InGaN active layer 320, y-axis indicates the mole fraction of In composition of AlGaInN barrier layer 310, and the linear line indicates the internal polarization field having a zero value.

As shown in the graph of FIG. 5, the internal polarization field can be approximately zero when In compositions (variable x and y) of active layer 320 and barrier layer 310 are approximately 0.05 and 0.11, respectively (black square (a) on the linear line). In this case, active layer 320 has the composition of In_{0.05}Ga_{0.95}N and barrier layer 310 has the composition of Al_{0.1}Ga_{0.79}In_{0.11}N. Further, at the black square (b) on the linear line (that is, x and y are 0.1 and 0.16, respectively), semiconductor device 300 has In_{0.1}Ga_{0.9}N active layer/Al_{0.1}Ga_{0.74}In_{0.16}N barrier layer, and the internal polarization field becomes approximately zero. Still further, at the black square (c) on the linear line (that is, x and y are approximately 0.15 and 0.21, respectively), semiconductor device 300 has In_{0.15}Ga_{0.85}N active layer/Al_{0.1}Ga_{0.69}In_{0.21}N barrier layer, and the internal polarization field becomes zero.

Accordingly, by using the linear line of the zero internal polarization field as shown in FIG. 5, In composition (y) of Al_{0.1}Ga_{0.9-y}In_{y}N barrier layer 310 and/or In composition (x) of InₓGa₁₋ₓN active layer 320 can be selected. In some embodiments, In composition (x) of InₓGa₁₋ₓN active layer 320 can be in a range of about zero (0) and 0.3, and In composition (y) of Al_{0.1}Ga_{0.9-y}In_{y}N barrier layer 310 can be in a range of about 0.01 and 0.3. In other embodiments, In composition (x) of InₓGa₁₋ₓN active layer 320 is in a range of about 0.05 and 0.15, and In composition (y) of Al_{0.1}Ga_{0.9-y}In_{y}N barrier layer 310 is in a range of about 0.1 and 0.22. The relationship between In composition (x) of InGaN active layer 320 and In composition (y) of AlGaInN barrier layer 310 can show a linear relationship.

In some embodiments, the relationship between III-V group compound semiconductor materials of an active layer and a barrier layer can show a non-linear relationship, such as logarithmic or exponential relationship in accordance with the type of the III-V group compound semiconductor materials of the active layer and the barrier layer and the variety of compositions of the III-V group compound semiconductor materials.

In some embodiments, the mole fractions of In compositions of InGaN active layer 320 and AlGaInN barrier layer 310 can be selected based on the amount of the compressive strain in a layer. Since the higher In composition (e.g., about 0.3 or more) of InGaN active layer 320 results in a larger compressive strain, and the growth of the strained layers is limited to a critical thickness, the lower In composition (e.g., about 0.01 to 0.30) of AlGaInN barrier layer 310 can be selected.

As described above, optical dipole matrix element Mₗₘ^{ησ}(\vec{k}_{∥}) in the quantum well increases as the internal polarization field decreases. Accordingly, by reducing the internal polarization field, the optical dipole matrix element can be increased and, thus, optical gain g(ω) can be enhanced. The change of the optical dipole matrix for different compositions of the barrier layer is illustrated in FIG. 6.

The graph shown in FIG. 6 illustrates a normalized optical matrix element (y-axis) for InGaN/AlGa_{1-y}In_{y}N semiconductor device 300 as a function (x-axis) of in-plane vectors for several In compositions of AlGa_{1-y}In_{y}N barrier layer 310. Here, the carrier density (N_{2D}) in active layer 320, i.e. the number of carriers in active layer 320 per a square meter, is about 20*10¹² cm⁻². As shown in the graph, the normalized optical matrix element is changed in accordance with In composition of AlGa_{1-y}In_{y}N barrier layer 310. Further, this graph shows that the normalized optical matrix element for InGaN/AlGa_{1-y}In_{y}N is enhanced as In composition (y) of AlGa_{1-y}In_{y}N barrier layer 310 becomes smaller. Thus, the normalized optical matrix element can be enhanced by controlling the composition of the barrier layer (e.g., In composition of AlGa_{1-y}In_{y}N barrier layer 310).

The graph shown in FIG. 7 illustrates an optical gain (y-axis) of InₓGa₁₋ₓN/AlGaInN semiconductor device 300 and InₓGa₁₋ₓN/GaN semiconductor device as a function (x-axis) of wavelength. Assuming that the variable x is 0.05, the peak optical gain of In_{0.5}Ga_{0.5}N/AlGaInN semiconductor device 300 is approximately 13000/cm, and the peak optical gain of In_{0.5}Ga_{0.5}N/GaN semiconductor device is approximately 8000/cm. The peak wavelength is shifted to shorter wavelength with the quaternary barrier layer (e.g., AlGaInN of barrier layer 310). InGaN/AlGaInN semiconductor device 300 has much larger optical gain than that of InGaN/GaN semiconductor device because the optical matrix element in InGaN/AlGaInN semiconductor device 300 is enhanced due to the disappearance of the internal polarization field.

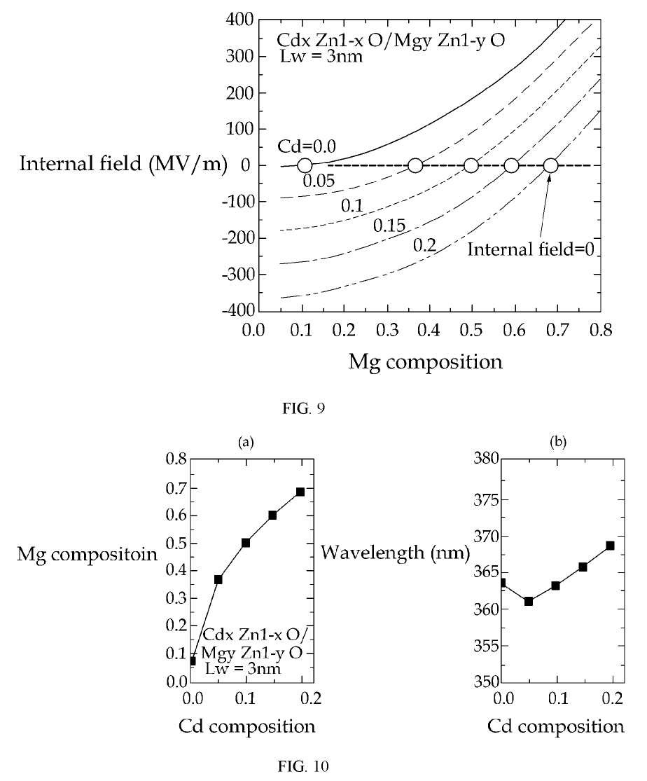

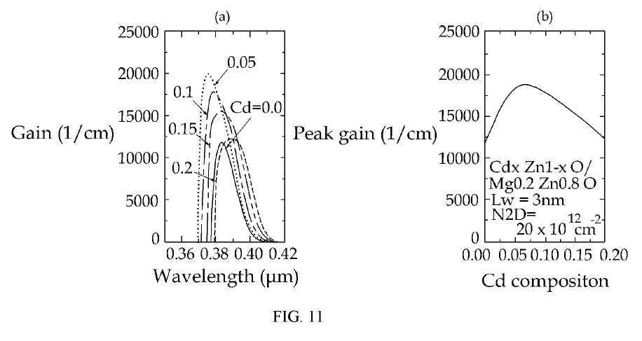

In another embodiment, a semiconductor device may have a II-VI group compound semiconductor material. Such a II-VI group compound semiconductor device will be described with reference to FIGS. 8-11. FIG. 8 is a schematic diagram of an illustrative embodiment of a II-VI group compound semiconductor device. FIG. 9 is a graph showing an internal polarization field as a function of Mg composition of the MgZnO barrier layer shown in FIG. 8. FIG. 10 shows graphs illustrating (a) the relationship between Mg composition of the MgZnO barrier layer and Cd composition of the CdZnO active layer shown in FIG. 8, and (b) a wavelength of the semiconductor device shown in FIG. 8 as a function of Cd composition of the CdZnO active layer. FIG. 11 shows graphs illustrating (a) an optical gain as a function of wavelength for different mole fractions of Cd compositions of the CdZnO active layer shown in FIG. 8, and (b) an optical gain as a function of different mole fractions of Cd compositions of the CdZnO active layer shown in FIG. 8.

As depicted in FIG. 8, a II-VI group compound semiconductor device 800 includes a CdZnO active layer 820 (i.e., an active layer composed of CdZnO), an upper MgZnO barrier layer 810 (i.e., an upper barrier layer composed of MgZnO) on a top surface of CdZnO active layer 820, and a lower MgZnO barrier layer 830 (i.e., a lower barrier layer composed of MgZnO) (which is optional) on a bottom surface of CdZnO active layer 820. In another embodiment, II-VI group compound semiconductor device 800 may have one barrier layer (e.g., upper MgZnO barrier layer 810) disposed on CdZnO active layer 820. CdZnO active layer 820 may have a thickness of several nanometers to several hundreds nanometers. For example, the thickness of CdZnO active layer 820 can be about 0.1 nm to 300 nm, or about 1 nm to 50 nm.

Upper and lower MgZnO barrier layers 810 and 830 each may have a thickness of several nanometers to several hundreds nanometers. For example, upper and lower MgZnO barrier layers 810 and 830 can each have a thickness of about 0.1 nm to 500 nm, or about 1 nm and to 100 nm. The II-VI group compound semiconductor material of the upper and lower barrier layers (e.g., MgZnO barrier layers 810 and 830) have wider band gaps than that of the II-VI group compound semiconductor material of the active layer (e.g., CdZnO active layer 820), thus forming a quantum well in the active layer (e.g., CdZnO active layer 820). In other embodiments, a II-VI group compound semiconductor material having a wider band gap than that of a II-VI group semiconductor material of the active layer can be selected for the upper and lower barrier layers.

CdZnO active layer 820 has a band gap of about 2.2 eV to 3.35 eV, and upper and lower MgZnO barrier layers 810 and 830 each have a band gap of about 3.35 eV to 5.3 eV. The band gaps of MgZnO compound semiconductor material and CdZnO compound semiconductor material can vary depending on the compositions of Mg, Zn or Cd. Thus, due to the differences between the band gaps of CdZnO active layer 820 and MgZnO barrier layers 810 and 830, a quantum well is formed in CdZnO active layer 820. As illustrated with respect to Equation (2) above, the internal polarization field in the quantum well can be reduced by controlling the mole fractions of the compositions of CdZnO active layer 820 and upper and lower MgZnO barrier layers 810 and 830.

With reference to the graph shown in FIG. 9, the internal polarization field (y-axis) in CdZnO active layer 820 for different Cd compositions and Mg compositions (x-axis) will now be described in detail. Here, assume that active layer 820 has a composition of CdₓZn₁₋ₓO (0≦x≦1) and a thickness of about 3 nm, and upper and lower barrier layers 810 and 830 each have a composition of Mg_{y}Zn_{1-y}O (0≦y≦1) and a thickness of about 3 nm to 15 nm. As described with respect to FIG. 4 above, the compositions of CdₓZn₁₋ₓO active layer 820 and upper and lower Mg_{y}Zn_{1-y}O barrier layers 810 and 830 may be controlled to make the internal polarization field in CdₓZn₁₋ₓO active layer 820 approximately zero.

As an example, when Cd composition of CdₓZn₁₋ₓO active layer 820 and Mg composition of upper and lower Mg_{y}Zn_{1-y}O barrier layers 810 and 830 are approximately zero and 0.1, respectively (that is, semiconductor device 800 has the active/barrier layers of ZnO/Mg_{0.1}Zn_{0.9}O), the internal polarization field becomes approximately zero. As another example, the internal field becomes approximately zero when the variables x and y are approximately 0.05 and 0.37, 0.1 and 0.5, 0.15 and 0.6, and 0.2 and 0.7, respectively. In the case where the variables x and y are 0.2 and 0.7, respectively, semiconductor device 800 has the active/barrier layers of Cd_{0.2}Zn_{0.8}O/Mg_{0.7}Zn_{0.3}O. When Cd composition (x) of CdₓZn₁₋ₓO active layer 820 is in the range of about zero (0) and 0.2, Mg composition (y) of upper and lower Mg_{y}Zn_{1-y}O barrier layers 810 and 830 can be in the range of about 0.01 and 0.8.

The relationship between Mg and Cd compositions is illustrated in graph (a) of FIG. 10. In graph (a), the solid line indicates when the internal polarization is zero. As illustrated in graph (a), Mg composition of upper and lower Mg_{y}Zn_{1-y}O barrier layers 810 and 830 can increase logarithmically in accordance with the increase of Cd composition of CdₓZn₁₋ₓO active layer 820 in the condition of zero internal polarization field. In this case, Mg composition of upper and lower Mg_{y}Zn_{1-y}O barrier layers 810 and 830 and Cd composition of CdₓZn₁₋ₓO active layer 820 are in a logarithmic relationship. In some embodiments, the relationship between II-VI group compound semiconductor materials of an active layer and a barrier layer can show a linear or a non-linear relationship, such as an exponential relationship, in accordance with the type of the II-VI group compound semiconductor materials of the active layer and the barrier layer and the variety of compositions of the II-VI group compound semiconductor materials.

Graph (b) in FIG. 10 illustrates the transition wavelength of semiconductor device 800 as a function of Cd composition of CdZnO active layer 820. As illustrated in graph (b), the transition wavelength of semiconductor device 800 can be changed by controlling Cd composition of CdZnO active layer 820. Therefore, Cd composition is selected based on a desirable transition wavelength for various optoelectronic devices. Further, Mg composition can be selected depending on the selected Cd composition to have substantially a zero internal polarization field in CdZnO active layer 820.

Graph (a) in FIG. 11 illustrates the optical gain (y-axis) of CdₓZn₁₋ₓO/Mg_{0.2}Zn_{0.8}O semiconductor device 800 for different Cd compositions, as a function of the transition wavelength (x-axis). As illustrated in graph (a), the optical gain is correlated to the Cd composition. That is, the optical gain can be changed by controlling Cd composition of CdₓZn₁₋ₓO active layer 820. Stated another way, as the Cd composition of CdₓZn₁₋ₓO active layer 820 changes, the optical gain and the transition wavelength varies. As can be seen in graph (a), when the mole fraction of Cd composition changes from zero to 0.05, the transition wavelength of semiconductor device 800 is shifted from right to left, that is, peak wavelength of semiconductor device 800 is reduced and the optical gain of semiconductor device 800 increases. As an example, when the mole fraction of Cd composition is about zero, the peak wavelength is approximately 0.385 μm, and the optical gain in the peak wavelength is approximately 12500/cm. As another example, when the mole fraction of Cd composition is 0.05 and the peak of the transition wavelength of semiconductor device 800 is approximately 0.375, the optical gain of semiconductor device 800 is approximately 20000/cm. Accordingly, the optical gain of semiconductor device 800 can be enhanced by controlling the mole fraction of Cd composition of CdₓZn₁₋ₓO active layer 820.

Graph (b) in FIG. 11 illustrates the peak gain (y-axis) of CdₓZn₁₋ₓO/Mg_{0.2}Zn_{0.8}O semiconductor device 800 as a function of Cd composition (x-axis) of CdₓZn₁₋ₓO active layer 820. Here the thickness of the quantum well is about 3 nm, and the carrier density (N_{2D}) in active layer 820, i.e. the number of carriers in active layer 820 per a square meter, is about 20*10² cm⁻². As illustrated in graph (b), the peak gain of semiconductor device 800 can be changed for different Cd compositions. For example, semiconductor device 800 can have the optical gain of approximately more than 17000/cm when the mole fraction of Cd in CdₓZn₁₋ₓO active layer 820 is approximately 0.07.

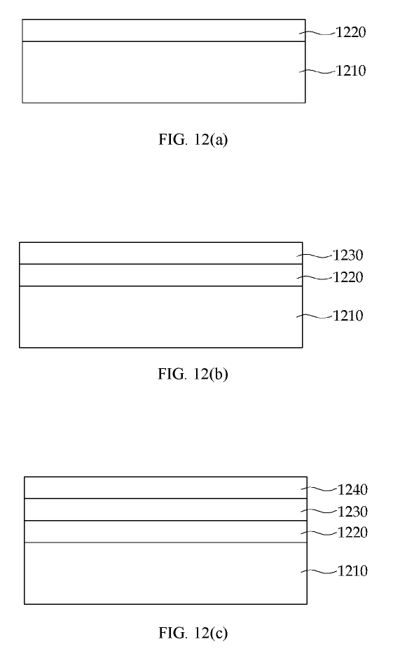

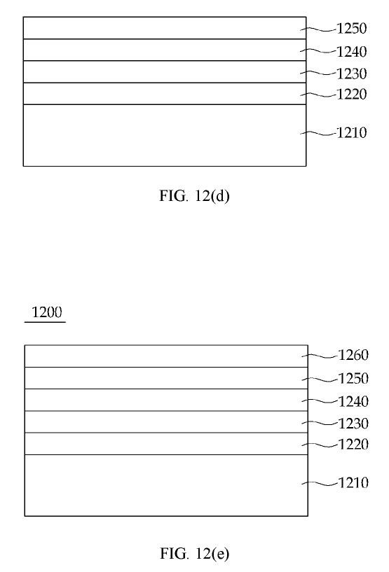

With reference to FIGS. 12(a)-12(e), a method for fabricating a semiconductor device in accordance with the present disclosure will now be described. FIGS. 12(a)-12(e) are schematic diagrams illustrating an illustrative embodiment of a method for fabricating a semiconductor device 1200.

As depicted in FIG. 12(a), a substrate 1210 is provided. Substrate 1210 can be composed of, for example, C-face (0001) or A-face (1120) oriented sapphire (Al₂O₃), silicon (Si), silicon carbide (SiC), spinel (MgAl2O4), aluminum nitride (AlN), gallium nitride (GaN), or aluminum gallium nitride (AlGaN). A buffer layer 1220 can be optionally formed on substrate 1210. Buffer layer 1220 can be made of a III-V group compound semiconductor material or a II-VI group compound semiconductor material. For examples, buffer layer 1220 can be made of GaN, AlGaN, AlN, SiC or ZnO-based compound semiconductor, such as ZnO or MgZnO. The material for buffer layer 1220 is not limited to the aforementioned III-V and II-VI groups, but may also include any material that establishes good structural quality. Buffer layer 1220 has a thickness of about 0.1 μm to 300 μm.

A lower barrier layer 1230 can be optionally formed over buffer layer 1220, as depicted in FIG. 12(b). Lower barrier layer 1230 can include a III-V group compound semiconductor material or a II-VI group compound semiconductor material. In some embodiments, a III-V group compound semiconductor material or a II-VI group compound semiconductor material for lower barrier layer 1230 can include a ternary or a quaternary compound semiconductor material. Suitable materials and thickness for lower barrier layer 1230 are substantially the same as the materials and thicknesses described above for lower barrier layer 110. Lower barrier layer 1230 can be formed using any of a variety of well-known deposition techniques or epitaxy techniques, such as radio-frequency (RF) magnetron sputtering, pulsed laser deposition, metal organic chemical vapor deposition (MOCVD), molecular beam epitaxy or radio-frequency plasma-excited molecular beam epitaxy. The composition of lower barrier layer 1230 can be adjusted by controlling the amount of precursor gases provided to a deposition device (e.g. MOCVD device) or by controlling the processing temperature or processing time.

As depicted in FIG. 12(c), an active layer 1240 is formed over lower barrier layer 1230. Active layer 1240 can include a III-V group compound semiconductor material or a II-VI group compound semiconductor material. The III-V group compound semiconductor material or II-VI group compound semiconductor material for active layer 1240 has a smaller band gap than that of the compound semiconductor material for lower barrier layer 1230 to form a quantum well in active layer 1240. Suitable materials and thickness for active layer 1240 are substantially the same as the materials and thicknesses described above for active layer 120. Active layer 1240 can be formed using any of the aforementioned well-known deposition techniques or epitaxy techniques.

As depicted in FIG. 12(d), an upper barrier layer 1250 is formed over active layer 1240. Upper barrier layer 1250 can be composed of the same material as lower barrier layer 1230. Suitable materials and thickness for upper barrier layer 1250 are substantially the same as the materials and thicknesses described above for upper barrier layer 110. Upper barrier layer 1250 can be formed using any of the aforementioned well-known deposition techniques or epitaxy techniques.

In some embodiments, lower barrier layer 1230 or upper barrier layer 1250 can be selectively formed on active layer 1230. For example, semiconductor device 1200 can have lower barrier layer 1230 disposed on a bottom surface of active layer 1230, upper barrier layer 1250 disposed on a top surface of active layer 1230, or both lower and upper barrier layers 1230 and 1250 disposed on the bottom and top surfaces, respectively, of active layer 1230.

As depicted in FIG. 12(e), an upper electrode 1260 can be optionally formed over upper barrier layer 1250. Upper electrode 1260 can include any conductive material, such as n-type doped semiconductor, p-type doped semiconductor, or metal. Upper electrode 1260 can include, without limitation, Al, Ti, Ni, Au, Ti/Al, Ni/Au, Ti/Al/Ti/Au, or any alloy thereof Upper electrode 1260 can be formed to have a thickness of about 1 nm to 300 nm, or a thickness of about 5 nm to 50 nm. Upper electrode 1260 may be formed using any of a variety of well-known techniques, such as sputtering, electroplating, e-beam evaporation, thermal evaporation, laser-induced evaporation, or ion-beam induced evaporation.

A semiconductor device (e.g., semiconductor device 1200) fabricated according to the illustrated method can reduce internal polarization field in a quantum well by forming one or more barrier layers (e.g., upper barrier layer 1250 and lower barrier layer 1230) of a III-V group or a II-VI group compound material on an active layer (e.g., active layer 1240) of a III-V group or a II-VI group compound material. Further, the semiconductor device can reduce the internal polarization field in the quantum well by controlling the mole fractions of a II-VI group compound material or a III-V group compound material in the active layer (e.g., active layer 1240) or the one or more barrier layers (e.g., upper barrier layer 1250 and lower barrier layer 1230). Through the reduction of the internal polarization field in the quantum well, the optical dipole matrix of the active layer (e.g., active layer 1240) is enlarged and the optical gain of the semiconductor device (e.g., semiconductor device 1200) enhanced.

In some embodiments, a photo-electric conversion device, an optoelectronic device, a quantized electronic device, a short wavelength emitter, a photo detector, a laser, a high electron mobility transistor, or a light emitting device in which the semiconductor device (e.g. semiconductor devices 100, 300, 800, and 1200) described above is installed can be provided.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A semiconductor device comprising:
an active layer composed of a first compound semiconductor material; and
one or more barrier layers disposed on either one side or both sides of the active layer and composed of a second compound semiconductor material, wherein a composition of the barrier layer is adjusted to increase an optical dipole matrix element of the active layer.

2. The semiconductor device of claim 1, wherein the optical dipole matrix element is increased by making a sum of an internal polarization field of the active layer and an internal polarization field of the one or more barrier layers zero.

3. The semiconductor device of claim 1, wherein a composition of the active layer is controlled in accordance with the composition of the one or more barrier layers.

4. The semiconductor device of claim 1, wherein a band gap of the first compound semiconductor material is smaller than that of the second compound semiconductor material.

5. The semiconductor device of claim 1, wherein the second compound semiconductor material comprises a ternary or a quaternary compound semiconductor material.

6. The semiconductor device of claim 1, wherein the first and the second compound semiconductors each comprise a III-V group compound semiconductor material or a II-VI group compound semiconductor material.

7. The semiconductor device of claim 1, wherein the first compound semiconductor material comprises GaN, InGaN, CdZnO, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, AlGaInAs, ZnO, ZnS, CdO, CdS, CdZnS, CdZnO, MgZnO, MgZnS, CdMgZnO, or CdMgZnS.

8. The semiconductor device of claim 1, wherein the second compound semiconductor material comprises AlGaInN, InGaN, AlGaN, AlGaP, AlGaAs, InGaN, InGaP, InGaAs, InAlN, InAlP, InAlAs, AlGaInP, AlGaInAs, CdZnS, CdZnO, MgZnO, MgZnS, CdMgZnO, or CdMgZnS.

9. The semiconductor device of claim 1, wherein the first compound semiconductor material comprises InₓGa₁₋ₓN (0≦x≦1) and the second compound semiconductor material comprises AlGa_{1-y}In_{y}N(0≦y≦1).

10. The semiconductor device of claim 9, wherein x is in the range of about 0 and 0.30 and y is in the range of about 0.01 and 0.30.

11. The semiconductor device of claim 1, wherein the first compound semiconductor material comprises CdₓZn₁₋ₓO (0≦x≦1) and the second compound semiconductor material comprises Mg_{y}Zn_{1-y}O(0≦y≦1).

12. The semiconductor device of claim 11, wherein x is in the range of about 0 and 0.20 and y is in the range of about 0.01 and 0.80.

13. The semiconductor device of 9, wherein a relation between x and y is linear.

14. The semiconductor device of 11, wherein the relation between x and y is logarithmic.

15. The semiconductor device of claim 1, wherein a thickness of the active layer is in the range of about 0.1 nm and 300 nm.

16. The semiconductor device of claim 1, wherein a thickness of each of the one or more barrier layers is in the range of about 0.1 nm and 500 nm.

17. A method for fabricating a semiconductor device comprising:
forming an active layer composed of a first compound semiconductor material on a substrate;
forming one or more barrier layers disposed on either one side or both sides of the active layer, the barrier layer composed of a second compound semiconductor material; and
adjusting the composition of the barrier layer to increase an optical dipole matrix element of the active layer.

18. The method of claim 17, wherein the first compound semiconductor material comprises a III-V group compound semiconductor material or a II-VI group compound semiconductor material, and the second compound semiconductor comprises a quaternary III-V group compound semiconductor material or a ternary II-VI group compound semiconductor material.

19. The method of claim 17, wherein at least one of forming the active layer and forming the one or more barrier layers comprise employing radio-frequency (RF) magnetron sputtering, pulsed laser deposition, metal organic chemical vapor deposition (MOCVD), molecular beam epitaxy, or radio-frequency plasma-excited molecular beam epitaxy.

20. The method of claim 19, wherein the composition of the one or more barrier layers is adjusted by controlling an amount of precursor gases or by controlling a processing temperature or processing time.
